(19) United States
(12) Patent Application Publication
(10) Pub. No.: US 2005/0260350 A1
(43) Pub. Date: Nov. 24, 2005

(54) Forming a conductor circuit on a substrate

(76) Inventors: Andrew Shipway, Jerusalem (IL); Itamar Willner, Mevasseret Zion (IL)

Correspondence Address: Nath & Associates, Sixth Floor, 1030 15th Street NW, Washington, DC, 20005, US

(21) Appl. No.: 10/466,070

(22) PCT Filed: Jan. 7, 2002
(86) PCT No.: PCT/IB02/00009

§ 371 Date: Dec. 30, 2003

(30) Foreign Application Priority Data
Jan. 16, 2001 (IL) 140912

(51) Int. Cl. B05D 5/12; B05D 3/10

(52) U.S. Cl. 427/304; 427/58

(57) ABSTRACT

Disclosed is a process for forming a conductor pattern on a face of a substrate, which is typically sorbing and porous, such as paper or cloth. The method comprises forming on the surface an exposed pattern of colloid particles, corresponding to the conductor pattern to be formed. The colloid particles suitable for use according to the invention are those that are capable of catalyzing electroless deposition of copper, silver, gold, and the like. After the exposed pattern of colloid particles is formed, precipitation of a metal substance on said face is caused, to form said conductor pattern.

### FIELD AND BACKGROUND OF THE INVENTION

The present invention concerns a method for forming a conductor pattern on a substrate.

Printed circuit boards (PCBs) are solid, rigid or flexible substrates with a conduction circuit printed thereon. The production of PCBs, by a variety of patterning techniques, is a time-consuming procedure, involving the use of noxious chemicals, particularly those needed for copper etching. The use of such chemicals adds costs and complexity to the procedure in view of the special disposal requirements of such chemicals.

### SUMMARY OF THE INVENTION

In the following, the term “conductor pattern” will be used to denote the conductor arrangement on the face of a substrate. This conductor pattern in fact defines the electrical conductivity between different portions of the substrate. For example, from one point of the substrate connected to one electronic component to another point which is connected to another component, to a current source, to an input/output connector, etc. The term “conductor pattern” should also be understood to encompass electronic components, such as resistors or capacitors, formed by conductor patches on the substrate.

In accordance with the invention, a conductor pattern is formed by a process involving the electroless deposition of a metal substance on a substrate. Metal colloid particles predeposited on the substrate act as catalysts for the redox reaction which is the basis of the metal deposition. The conductor pattern may be formed in a number of ways. In accordance with one embodiment, the colloid particles are distributed essentially uniformly on at least a portion of the face of the substrate. A barrier layer which masks the colloid particles is deposited thereon, the barrier layer being patterned to leave voids which correspond to the conductor pattern. Then after applying onto or contacting said face with a developing solution, the conductor pattern is obtained.

In accordance with another embodiment, the pattern of the conductor is a result of a patterned deposition of the colloid particles.

The substrate may be made of a pliable or flexible material or may be made of a rigid material. The substrate material may be porous, e.g. made of paper or cloth; the substrate may only have a porous surface formed or attached to a non-porous material; or may be made entirely of a non-porous material. A porous surface is preferred for some applications as it permits the colloid particles to be easily sorbed onto the surface. It is clear, however, that sorbing of the colloid particles to the surface may also be achieved by other means, e.g. chemical binding, by electrostatic interactions and others, as will also be detailed further below. While the substrate is typically flat substrate bodies with a three-dimensional structure may also be used.

### BRIEF DESCRIPTION OF THE DRAWINGS

The invention will be illustrated below with reference made at times to the annexed drawings. As will be appreciated, the illustrated embodiments are examples only of the much broader scope of the invention as defined herein.

In the drawings:

FIG. 1 is an illustration of a manner of forming a conductor pattern on a substrate, in an experiment carried out in accordance with the present invention. Also shown in FIG. 1 is an illustration of a manner of testing of the properties of the formed conductor pattern in such experiments.

FIG. 2 is a schematic illustration of the process of the invention in forming conductor patterns on opposite faces of the substrate, with and without through holes serving as conductors between the two faces.

FIGS. 3A and 3B show the two opposite faces of a paper substrate with different conductor patterns on each side, with conducting through holes connecting between conducting portions on both faces.

FIG. 4 is an illustration of a conductor pattern formed on paper in experiments carried out in accordance with the invention.

FIG. 5 is an illustration of the process in accordance with another embodiment of the invention in which the colloid particles are deposited directly in a patterned fashion on a substrate.

FIG. 6 shows an embodiment of the invention for forming a multilayer conducting pattern.

FIG. 7 illustrates another embodiment for forming a multilayer conductor pattern.

FIG. 8 is a further embodiment for forming a multilayer conductor pattern.

### DETAILED DESCRIPTION OF THE INVENTION

The present invention provides a process for forming a conductor pattern on a face of the substrate which comprises first forming an exposed pattern of metal colloid particles on said face, the particles being of a kind that can catalyze the electroless precipitation of a metal. Said pattern corresponds to that of the conductor pattern. Then a metal substance is caused to be deposited on said face, with the colloid particles acting as catalyzers of such precipitation.

In accordance with one, preferred embodiment of the invention the substrate is a sorbant substrate, and the colloid particles are sorbed thereon. An example of such a substrate is such made of a porous material with the colloid particles being impregnated therein. Typical examples of porous substrates are paper, woven or non-woven fabric made of natural or synthetic fibers and others.

In accordance with another embodiment, the substrate is chemically treated or has a priori, properties which permit it to bind colloid particles by one of a variety of different types of interactions. Such interactions may be electrostatic, hydrophobic, covalent or Van der Waals interaction. In order to permit the colloid particles to undergo such interactions, they may be at times be pretreated by attaching a variety of functional groups to them. In the case of a porous substrate, the colloid particles may be sprayed with the colloid particles that are then absorbed on such a substrate (e.g. paper); by being trapped within the porous structure of the substrate and by some molecular interactions, the colloid particles remain within the substrate matrix. Lipophilic particles may be made to attach to a substrate by hydrophobic interactions as they do not redissolve in an aqueous developer solution. In the case of charged particles, they may be made to attach to a surface by treating the surface such that it becomes oppositely charged. Thus, for example, if the colloid particles are negatively charged (e.g. they contain negatively charged groups such as carboxylates), they may be made to attach to a surface by treating the surface to make it positively charged, (e.g. by treating the surface with a thin film of 3-aminopropyltriethoxysilane).

The face of substrates may also be subjected to one of a number of other treatments for the purpose of causing the surface to be able to sorb the colloid particles. For example, the surface may be modified by forming thereon or attaching thereto a porous layer.

The colloid particles, in accordance with the preferred embodiment, are selected from palladium, gold and silver colloids, with palladium colloids being particularly preferred.

Particles are typically of a sub-micron size, the particles with a size within the range of 1-100 nm being preferred. Such particles have a high surface area and are easily dispersed in solvent and processed.

The metal, which is deposited from a solution onto the face of the substrate to form the conductor pattern, is preferably copper, silver or gold.

In accordance with an embodiment of the invention there is provided a process for forming a conductor pattern on a face of a substrate which comprises essentially uniformly depositing metal colloid particles on at least a portion of the face, then depositing a barrier layer on a substrate which can mask the colloid particles from contact with chemicals which are subsequently applied onto or contacted with the surface, with the barrier layer being patterned such that voids are left that corresponds to the conductor pattern. Then the treated portion of the face is contacted with a developing solution that causes the formation of a metal layer onto exposed substance surface with colloid particles and incubating for a time sufficient to form the conductor pattern.

In accordance with the above embodiment, colloid particles are essentially uniformly sprayed over the substrate or at least a portion thereof and then the barrier layer is applied onto the substrate which acts to mask the colloid particles from chemicals which are applied to or contacted with the treated face of the substrate at a subsequent step. The barrier layer is patterned such that voids are left which correspond to the desired conductor pattern. Consequently, when a developing solution is applied, a metal precipitates only on the exposed substrate surface and so the conductor pattern is formed. The barrier layer may conveniently be deposited by a process built upon a conventional printing process. However, as will no doubt be appreciated, the invention is not limited thereto. In a printing process a layer of an ink or another material is applied in a surface in a predetermined pattern. In modern printing technology this pattern is usually computer-controlled. It was found in accordance with the invention that conventional printing, e.g. using a laser printer, can deposit the barrier layer. The printed material may be conventional ink, may be selected from a variety of miscible substance that can form a barrier layer upon drying of their solvent, may be a liquid that polymerizes to form liquid-impermeable or retarding film on areas on which it is applied, etc. It should be noted that rather than using a printer, a hand-held device in the form of pen or another, may be used for the purpose or forming a patterned protecting layer. This is particularly useful for home application, application in a students laboratory and others.

One advantage in the printing technique is that it is very rapid and a large number of substrates with a printed circuit can be produced over a short period of time. Additionally, in this way a computerized control of the process of forming a conductor pattern in accordance with the invention, permits to easily and cheaply custom produce a conductor pattern for a specific use. Essentially, using the process of the invention a single, custom-designed conductor pattern may be produced with the same ease as one of a batch of a large number of substrates all with the same conductor pattern.

In a typical process, in accordance with the invention, a substrate, e.g. a substrate made of a porous material such as paper, non-woven fabric, etc., is treated to deposit thereon metal colloid particles suspended in a solvent, and then the solvent is permitted to dry. The treatment may be by soaking the substrate in a solution of the colloids, by spraying, etc. The substrate impregnated with the colloid particles is then introduced into a printing apparatus which prints a protective barrier layer, e.g. ink, leaving voids which trace the pattern of the desired conductor or circuit. Alternatively, a pattern of a barrier layer may be formed by a pen-like device as noted above. At a subsequent step, the treated face of the substrate is contacted with a developing solution that gives rise to the electroless deposition of a metal which may be copper, gold, silver or other. In this way a conductor pattern is formed on one face—the treated face, of the substrate.

At times conductor patterns are formed on both faces of a thin, flat substrate such as paper. In order to link conducting portions of both faces of the substrate, holes may be formed in the substrate and following the electroless deposition the walls of the holes will become conducting as well, electrically linking the conducting portions on both faces. Where the substrate is made of a porous material holes may at times be formed after impregnation of the substrate with the colloid particles. Given the porous nature of the substrate, the walls of the holes may already be impregnated with the colloid particles which will then catalyze the electroless deposition reaction yielding a deposition of metal film on these walls. The holes may obviously also be formed prior to said impregnation. Also in case that a substrate is made of a non-porous material, holes may first be formed and the deposition of the colloid particles on the substrates may follow thereafter.

The process of the invention permits also the formation of a substrate with a plurality of layers of conductors. In accordance with one embodiment, the different layers are formed with an intermediate insulated layer between them. In accordance with this embodiment an electrically non-conducting layer is deposited over the conductor of the first layer, a pattern of exposed colloid particles is then formed on the surface (the pattern may be performed as described above or by direct printing of a colloid particle pattern as will be further described below) and then, in a similar manner as described above, by electroless deposition of a metal a conductor pattern is formed. In this manner, a plurality of conducting layers on a substrate may be formed. Connectivity between different layers may be provided through holes, either such formed a priori or holes formed at the end of the process combined with an electroless deposition process to coat the walls of the holes with a metal.

In accordance with another embodiment of the invention each conductor layer is formed directly over the previous layer which permits the formation of a three-dimensional conductor pattern. A non-conducting substance may be applied on portions of a certain layer which are not made into a conductor.

In accordance with another embodiment of the invention a conductor pattern is formed by a patterned deposition of the colloid particles on the substrate. This may be performed by a printing-like process or by using a hand-held device, e.g. a pen-like device. In a manner similar to that described above, mutatis mutandis, a conductor pattern may be formed on opposite faces of the substrate, a multi conductor layer may be formed and also holes may be made to serve as conductors between layers or faces.

### DESCRIPTION OF SPECIFIC EMBODIMENTS

Several embodiments are described below. As will no doubt be understood, the description serves to illustrate the invention and should not be construed as limiting.

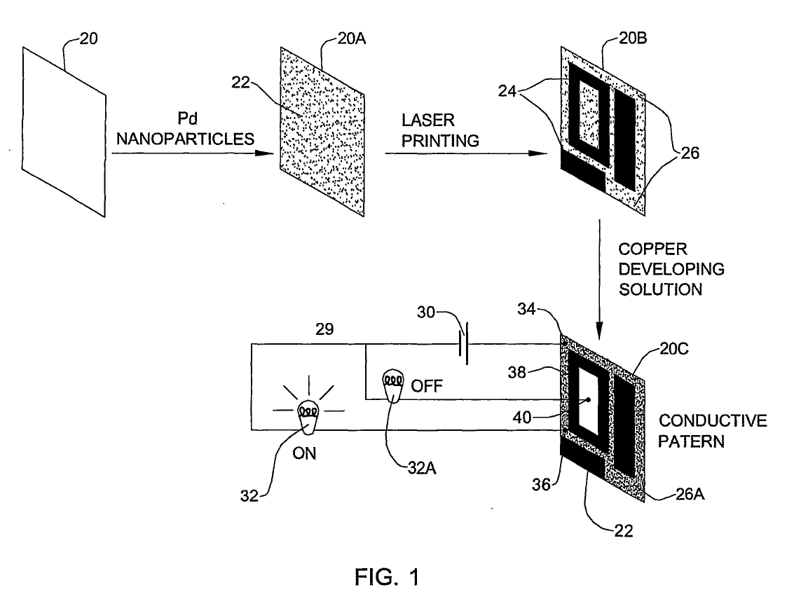

Reference is first made to FIG. 1 giving an outline of the procedure for preparing a conductor pattern on an ordinary paper, in the experiment which is described in the Example below. A sheet of paper 20 is treated so that at least one of its faces 22 is impregnated with nanoparticles, such as palladium nanoparticles. The treatment process may comprise soaking the substrate with a solution containing the colloid particles, spraying the colloid particles on the treated face, etc. The treated paper 20A is then introduced into a printer, such as a laser printer and then through a printing process, a print 24 is applied leaving non printed voids 26. This pattern-printed paper 20B is contacted with a developing solution giving rise, through electroless deposition, to the formation of a conductor pattern 26A over the face 22 to yield a conductive pattern carrying substrate 20C.

The conductivity can be verified by using a simple test circuit 29 with a power source 30 and a light bulb 32 which lights up when two ends of the circuit are connected to points 34 and 36 linked by a conducting strip 38. When the other end of the test circuit is connected to point 40, bulb 32A does not light up. This demonstrates the selective formation of a conductor pattern on portions not shielded by the printed pattern 24.

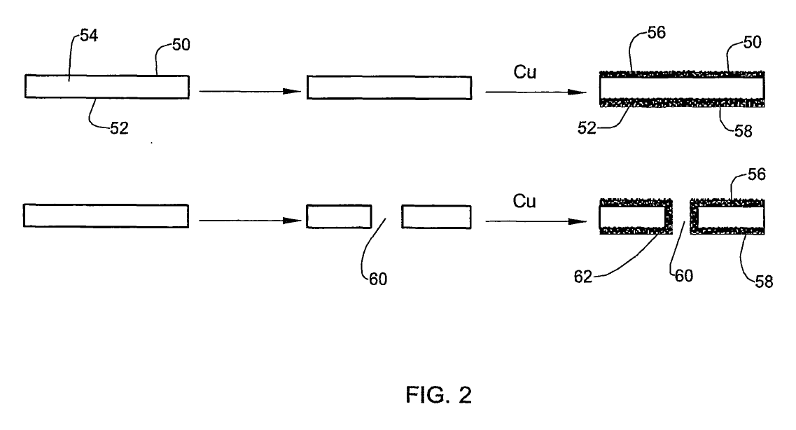

FIG. 2 shows two alternative embodiments of forming conductor patterns on two opposite faces 50 and 52 of a substrate, e.g. a paper substrate. In the upper scheme a palladium treated paper substrate 54 is treated in a similar manner to that shown in FIG. 1 to yield conductor patterns 56 and 58 on faces 50 and 52, respectively. In this scheme there is no connectivity between conducting portions of patterns 56 and 58. In the other scheme, a hole 60 is formed in the substrate and consequently a conductor film is formed also on the walls 62 of hole 60 thus connecting between conducting portions of patterns 56 and 58.

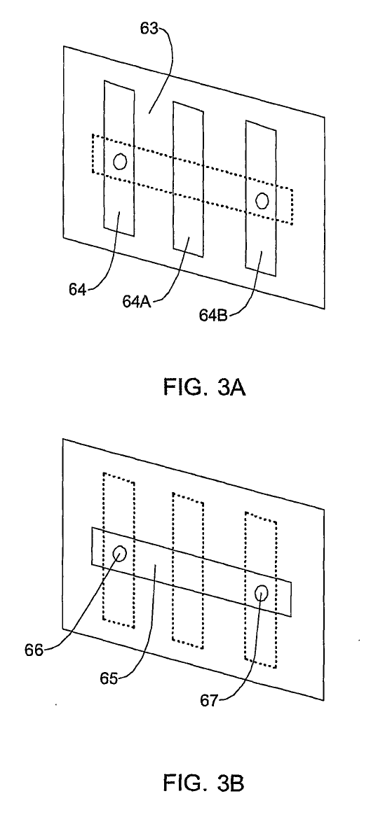

FIGS. 3A and 3B illustrate a substrate 63 with conductor patterns formed on both its faces. These conductor patterns include three parallel rectangular conductor patches 64, 64A and 64B on one face of substrate 63 and a transverse conductor patch 65 on the other face. Holes 66 and 67 are formed linking patches 64 and 64B with patch 65 on the other face. Experiments conducted in accordance with the invention have demonstrated that an electrical link is thereby formed between patches 64 and 64B, with patch 64A being electronically isolated from both patches 64 and 64B.

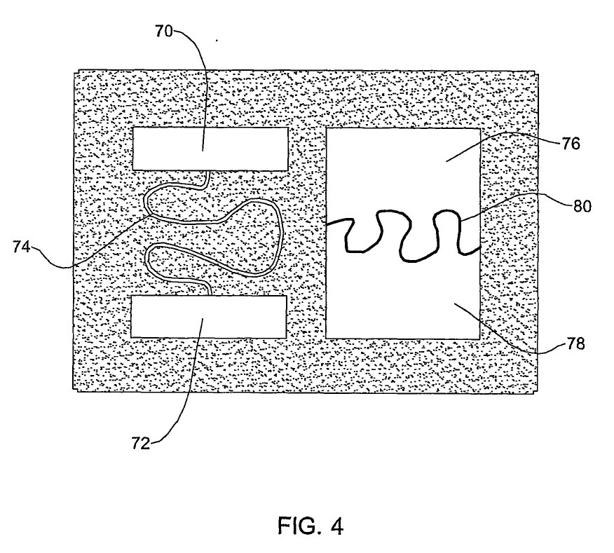

Conductor patterns formed in experiments carried out in accordance with the invention and reported below in the example, are shown in FIG. 4. In the left-hand side, conductor patches 70 and 72 are linked to one another by a narrow conducting line 74 which in this case has a width of 0.5 mm. Such a wire in fact defines a resistor between the two conductor patches 70,72.

In the right-hand side, two conductor patches 76 and 78 are separated from one another by a tortuous non-conducting gap 80. While current can flow between patches 70 and 72 through line 74, no current can flow between patches 76 and 78. As will be appreciated, if the tortuous non-conducting line will be made long enough to trace a considerable length, these two conductor patches may in fact define two electrodes of a capacitor.

Thus, it is clear that in accordance with an invention it is also possible to form electric components such as a resistor or a capacitor directly on the substrate.

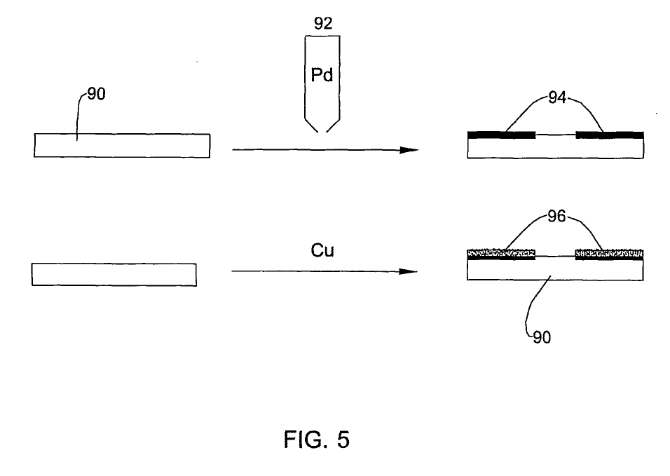

In the embodiment shown in FIG. 1, the entire paper is impregnated with palladium nanoparticles. Another embodiment is shown in FIG. 5. A porous substrate such as paper substrate 90 is printed on, by a printing head 92 with colloid particles, such as palladium nanoparticles to yield an impregnated pattern 94. Then, following an electroless precipitation, for example of copper, a conductor pattern 96 is formed on substrate 90.

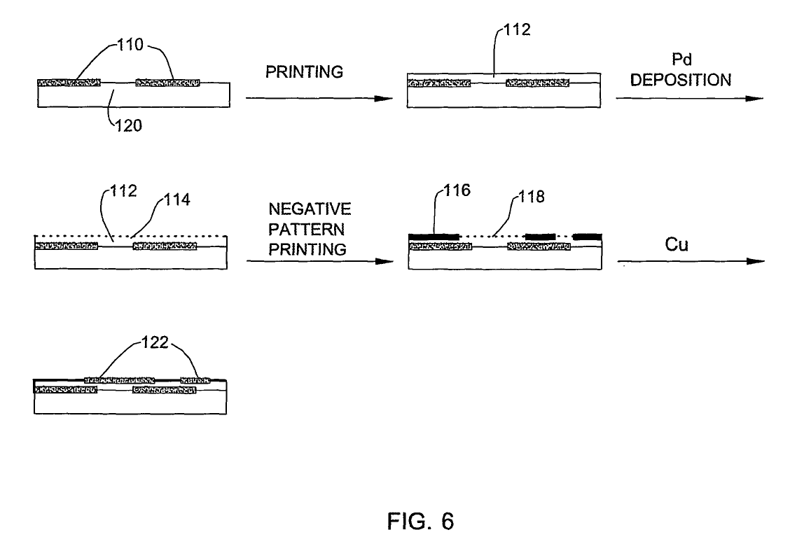

One embodiment of forming a multi-layer conductor pattern on a substrate is shown in FIG. 6. First layer conductor pattern 110 is formed on substrate 120 in a manner as described before. Then, by a printing-like process a non-conducting (insulating) layer 112 is formed. Then palladium is deposited on the substrate and is immobilized thereon. The immobilization of the palladium nanoparticles 114 over layer 112 may be achieved by a variety of means such as ionic interaction, Van der Waals interaction, covalent binding, etc. Then by a negative pattern printing, in a similar manner to that shown in FIG. 1, protected portions 116 and non-protected portions 118 are thus defined and following an electroless deposition process, a second conductor pattern 122 is thereby formed.

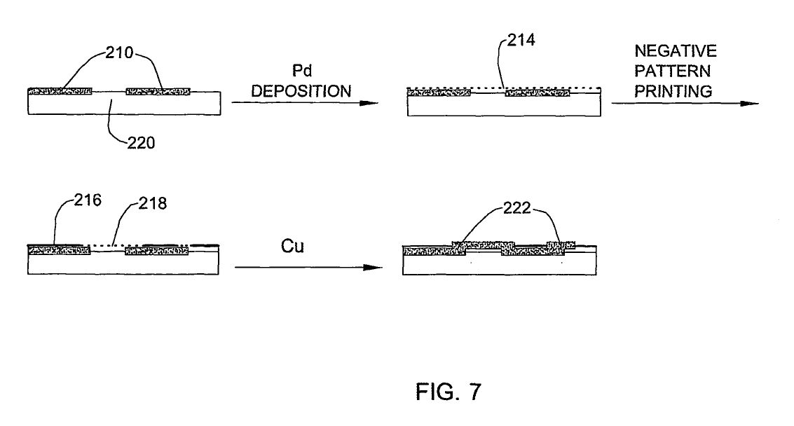

FIG. 7 shows another process for forming a multi-layer conductor pattern. The entire process is somewhat similar to that shown in FIG. 6 and like components were thus given like reference numerals shifted by 100. The difference between the embodiment of FIG. 6 and that of FIG. 7 is that in the embodiment of FIG. 6, no non-conducting layer such as layer 112 between the different conductor patterns is formed. Thus, in this way, direct connectivity between conductor portions of different layers may be formed. Overall, this manner permits the design of a three-dimensional conductor pattern.

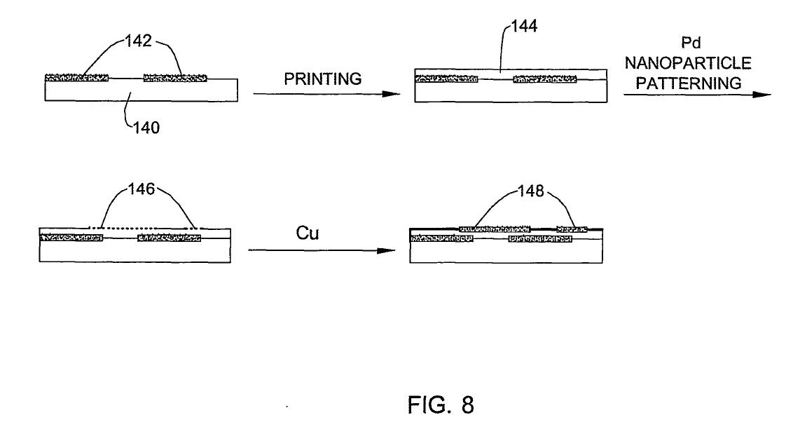

Another embodiment for forming a multi-layer conductor pattern in accordance with the invention is shown in FIG. 8. A substrate 140 with a first layer conductor pattern 142 is first printed with an insulating layer 144. Then palladium particles or any other colloid particles 146 are then deposited in a patterned manner, in a printing-like procedure and then following an electroless deposition process a second conductor pattern 148 is formed.

It will be appreciated that in the same manner shown herein (in FIGS. 6-8) to form a two-layer conductor pattern, multi-layers may be formed.

EXAMPLE

Pd-Nanoparticles:

Palladium nanoparticles were synthesized according to a literature procedure (P. C. hidber, W. Helbig, E. Kim, G. M. Whitesides, Langmuir, 12:1375-1380, 1996). Palladium (II) acetate (0.5 g, 2.23 mmol) and tetraoctadecylammonium bromide (625 mg, 0.56 mmol) were suspended in a mixture of toluene (20 mL) and THF (4 mL). Ethanol (3 mL) was added, then the mixture was stirred at reflux for 15 hours. After the reaction was cooled, ethanol (20 mL) was added and the nanoparticles were left for 24 hours to precipitate. The supernatant was decanted, then further ethanol (50 mL) was added, the nanoparticles were allowed to settle, and the supernatant was again decanted. The remaining slurry was dried under vacuum.

Pd-Treatment of the Paper:

Ordinary white laser printer paper was used. The dry Pd nanoparticles were dissolved in toluene at a concentration of 10 mg mL⁻. This solution was sprayed on the paper at approximately 1 mL per 100 cm² (i.e. at a Pd-density of 0.1 mg cm⁻²), then the paper was allowed to dry in the air.

Laser Printing:

Laser printing was performed on a Tektronix Phaser 740 laser printer, printing at a resolution of 600 dots per inch (dpi).

Copper Deposition:

The electroless deposition of copper was achieved by a literature method (H. Niino, A. Yabe Appl. Phys. Lett., 60:2697-2699, 1992). Two solutions (‘A’ and ‘B’) were mixed in a 10:1 ratio and the patterned colloid-treated paper was floated on the surface of the mixture. One mixture could be used for many samples with little loss of efficiency. After an allotted time (usually 5 minutes), the paper was removed, then rinsed first in water, then in acetone and allowed to dry. Solution ‘A’ contained CuSO₄ (3 g), sodium potassium tartrate (14 g) and NaOH (4 g) in deionised water (100 mL), and solution ‘B’ was aqueous formaldehyde (37%).

The copper thickness can be increased by either a longer treatment time in the plating bath, or a higher initial concentration of Pd nanoparticles.

Even when printed on both sides, the paper itself remained insulating (i.e. the two sides are electrically isolated from each other) (FIG. 2, upper scheme). If, however, a hole was made in the paper prior to the copper treatment, the sides of the hole were also covered in copper, allowing electrical communication between two sides (FIG. 2, lower scheme) (FIG. 3).

The resolution of a standard laser printer is 600 dpi, i.e. ca. 50 μm. The procedure should also work by use of inkjet printers.

A typical paper sample immersed in the bath for 5 minutes gives a resistance of 300 Ω for a wire 11.5 cm long and 0.05 cm wide, and 80000 Ω for a 9 cm long break between two electrodes 0.05 cm apart (FIG. 4).

A substrate other than paper, such as cellulose acetate may also be used. In such a case a much smaller amount, e.g. a tenth, of the amount of colloid used in the case of paper is needed to produce similar results as the substrate is not porous. However, in order to apply the colloid particles on the surface of the substrate in such a case, a pre-treatment may be needed, e.g. one of these mentioned above.

1. A process for forming a conductor pattern on a face of a substrate, comprising:
Forming an exposed pattern of metal colloid particles on said face, the particles being capable of catalyzing electroless deposition of a metal, the pattern corresponding to that of the conductor pattern; and causing precipitation of a metal substance on said face to form said conductor pattern.

2. A process according to claim 1, wherein the substrate is made of a sorbing substrate and the colloid particles are sorbed therein.

3. A process according to claim 2, wherein said surface is made of porous material and the colloid particles are impregnated therein.

4. A process according to claim 3, wherein the substrate is made of paper or cloth.

5. A process according to claim 1, comprising initially treating the surface to permit the surface to sorb the colloid particle and then sorbing the colloid particles on the treated surface.

6. A process according to claim 1, wherein the colloid particles are made to covalently or electrostatically bind to said face.

7. A process according to any one of claims 1-6, wherein the colloid particles are selected from palladium, gold and silver colloids.

8. A process according to claim 7, wherein the particles are palladium colloids.

9. A process according to any one of claims 1-8, wherein the particles have a diameter within the range of 1-100 nm.

10. A process according to any one of claims 1-9, wherein the surface of the particles is functionalized to enhance their ability to be attached to the substrate.

11. A process according to any one of claims 1-10, wherein said metal substance is copper, silver or gold.

12. A process for forming a conductor pattern on a face of a substrate, comprising:
(a) essentially uniformly depositing metal colloid particles on at least a portion of said face, the particles being capable of catalyzing electroless deposition of a metal;
(b) depositing a barrier layer on the substrate, the barrier layer masking the colloid particles from contact with chemicals subsequently applied onto or contacted with the surface and being patterned such that voids are left corresponding to the conductor pattern; and
(c) contacting said portion with a developing solution that causes precipitation of a metal layer onto an exposed substrate surface that has colloid particles and incubating for a time sufficient to form the conductor pattern.

13. A process according to claim 12, comprising forming a first conductor pattern with first conducting portions on a first face of a planar substrate and a second conductor pattern with second conducting portions on the second, opposite face of the planar substrate.

14. A process according to claim 13, comprising forming one or more holes within the substrate before step (c), linking portions in the first and the second faces that will eventually become first and second conducting portions, respectively, and within step (c) causing deposition of the metal on the walls of the one or more holes, to form a conductor between said first and said second conducting portions.

15. A process according to any one of claims 12-14, comprising the following steps:
(d) depositing an electrically non-conducting layer on said portion;
(e) forming an exposed pattern of metal colloid particles on the non-conducting layer, said particles being capable of catalyzing electroless deposition of a metal, the pattern corresponding to that of a conductor pattern; and
(f) contacting the exposed pattern with a developing solution that causes deposition of a metal layer onto a substrate comprising the colloid particles and incubating for a time sufficient for forming a conductor layer with said conductor pattern.

16. A process according to claim 15, wherein step (e) comprises:
(i) depositing metal colloid particles essentially uniformly over at least a portion of said non-conducting layer, the particles being capable of catalyzing electroless deposition of a metal substance; and
(ii) forming a barrier layer on the substrate, the barrier layer masking the colloid particles from contact with chemicals subsequently applied onto or contacted with the surface and being patterned such that voids are left corresponding to the conductor pattern.

17. A process according to claim 15 or 16, comprising repeating steps (d)-(f) one or more times.

18. A process according to any one of claims 12-17, wherein the barrier layer is formed by printing.

19. A process according to any one of claims 12-14, comprising the following steps:
(d) forming an exposed pattern of metal colloid particles on the conductor layer, said particles being capable of catalyzing electroless deposition of a metal, the colloid pattern corresponding to that of the intended conductor pattern;
(e) contacting the exposed pattern with a developing solution that causes deposition of a metal layer onto a substrate comprising the colloid particles and incubating for a time sufficient for forming a conductor layer with said conductor pattern.

20. A process according to claim 19, wherein step (d) comprises:
(i) essentially uniformly depositing metal colloid particles on at least a portion of the conductor layer, the particles being capable of catalyzing electroless deposition of a metal substance; and
(ii) depositing a barrier layer on said face, the barrier layer masking the colloid particles from contact with chemicals subsequently applied onto or contacted with said face and being patterned such that voids are left corresponding to an intended conductor pattern.

21. A process according to claim 19 or 20, comprising repeating steps (c)-(f) one or more times.

22. A process according to any one of claims 12-17, wherein the barrier layer is formed by printing.

23. A process for forming a conductor pattern on a substrate, comprising:
(a) depositing metal colloid particles on the substrate, the particles forming a pattern corresponding to that of the intended conductor pattern and being capable of catalyzing electroless deposition of a metal; and
(b) contacting the deposited colloid particles with a developing solution that causes deposition of a metal layer onto substrate portions that contain the colloid particles and incubating for a time sufficient for forming the conductor pattern.

24. A process according to claim 23, comprising the following steps:
(c) depositing an electrically non-conducting layer on said portion;
(d) forming an exposed pattern of metal colloid particles on the non-conducting layer, said particles being capable of catalyzing electroless deposition of a metal substance, the pattern corresponding to that of a conductor pattern; and
(e) contacting the exposed pattern with a developing solution that causes deposition of a metal layer onto a substrate comprising the colloid particles and incubating for a time sufficient for forming the conductor pattern.

25. A process according to claim 24, wherein step (d) comprises:
Depositing metal colloid particles in a pattern over said non-conducting layer, the pattern corresponding to a desired conductor pattern, the colloid particles being capable of catalyzing electroless deposition of a metal substance.

26. A process according to any one of claims 24-26, wherein the deposition of the pattern of colloid particles is performed by printing.

27. A process according to any one of claims 24-27, comprising forming a first conductor pattern with first conducting portions on a first face of a planar substrate and a second conductor pattern with second conducting portions on the second, opposite face of the planar substrate.

28. A process according to claim 23, comprising forming one or more holes within the substrate before step (b), linking portions in the first and the second faces that will eventually become first and second conducting portions, respectively, and within step (b) causing deposition of the metal on the walls of the one or more holes, to form a conductor between said first and said second conducting portions.
